(19) United States
(12) Patent Application Publication
(10) Pub. No.: US 2024/0105450 A1
(43) Pub. Date: Mar. 28, 2024

(54) GROUP III-V SEMICONDUCTOR DEVICE AND METHOD OF FABRICATION OF SAME INCLUDING IN-SITU SURFACE PASSIVATION

(71) Applicant: TEXAS INSTRUMENTS INCORPORATED, Dallas, TX (US)

(72) Inventors: Yoganand Saripalli, Allen, TX (US); Russell Fields, Sachse, TX (US); Brian Goodlin, Plano, TX (US); Qhalid Fareed, Plano, TX (US)

(21) Appl. No.: 18/090,766

(22) Filed: Dec. 29, 2022

Related U.S. Application Data
(60) Provisional application No. 63/409,477, filed on Sep. 23, 2022.
(60) Provisional application No. 63/423,722, filed on Nov. 8, 2022.

(51) Int. Cl. H01L 21/02; C23C 16/30; C23C 16/44; C30B 25/08; C30B 29/40; H01J 37/32

(52) U.S. Cl. CPC H01L 21/02661; C23C 16/301; C23C 16/4405; C30B 25/08; C30B 29/40; H01J 37/32357; H01J 37/32862; H01L 21/0217; H01L 21/02271; H01L 21/0242; H01L 21/0254; H01L 21/0262; H01L 21/02664; H01J 37/32816; H01J 2237/332

(57) ABSTRACT

A Group III-V semiconductor device and a method of fabricating the same including an in-situ surface passivation layer. A two-stage cleaning process may be effectuated for cleaning a reactor chamber prior to growing one or more epitaxial layers and forming subsequent surface passivation layers, wherein a first cleaning process may involve a remotely generated plasma containing fluorine-based reactive species for removing Si_{X}N_{Y} residual material accumulated in the reactor chamber and/or over any components disposed therein.

### CROSS-REFERENCE TO RELATED APPLICATIONS

This non-provisional application claims priority based upon (i) U.S. provisional Application No. 63/409,477, filed Sep. 23, 2022; and (ii) U.S. provisional Application No. 63/423,722, filed Nov. 8, 2022; each of which is hereby incorporated by reference in its entirety.

### FIELD OF THE DISCLOSURE

Disclosed implementations relate generally to the field of semiconductor devices and associated fabrication methods. More particularly, but not exclusively, the disclosed implementations relate to a Group III-V semiconductor device and a method of fabricating the same including an in-situ surface passivation layer.

### BACKGROUND

A compound semiconductor may be composed of two different chemical elements belonging to the same Group in the periodic table, (e.g., Group IV), or two or more different Groups in the periodic table, e.g., Ill and V. Compound semiconductors have unique material properties, such as direct energy bandgap, high breakdown electric fields, and high electron mobility, compared to silicon. Because of their unique properties, compound semiconductors are being explored as a replacement to silicon in a variety of applications, e.g., photonics, high-speed, and high-power device technologies.

The possibility to grow thin-films made of binary, ternary, and quaternary III-V alloys with different fractions of their constituent elements allows for the precise engineering of their optoelectronic and material properties. In addition, since many III-V compounds are direct-bandgap semiconductors, they are particularly suitable for the development of photonic devices and integrated circuits, especially where monolithic integration is required.

For Group III-V compound semiconductors to become widespread in future high-speed and low-power digital applications, however, microelectronic devices formed of III-V materials need to be integrated onto large substrates such as, e.g., silicon wafers. A unified, vigorous heterogeneous integration scheme of Group III-V materials on silicon or other suitable substrates is expected to allow high-speed, low-voltage III-V based transistors, while avoiding the need for developing large diameter III-V substrates. Besides transistor applications, successful integration of III-V layers on silicon can give rise to the opportunities for integrating new functionalities and features on silicon, such as, e.g., integrating logic circuit, optoelectronic and communication platforms on the same silicon wafer. However, heterogeneous integration of III-V materials on silicon imposes many significant technical challenges because of the large lattice mismatch between the two materials.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to a Group III-V semiconductor device and a method of fabricating the same including an in-situ surface passivation layer. A two-stage cleaning process may be effectuated for cleaning a reactor chamber prior to growing one or more epitaxial layers and forming subsequent surface passivation layers. In one arrangement, a cleaning process may involve applying a remotely generated plasma containing fluorine-based reactive species for removing Si_{X}N_{Y} residual material accumulated in the reactor chamber and/or over any components disposed therein. In some examples, a chlorine-based chemistry may be applied in a cleaning process for removing Ga_{y}N_{z} residual material following the removal of Si_{X}N_{Y} residual material. In some arrangements, the chlorine-based chemistry may be applied before the application of the plasma containing fluorine-based reactive species.

### BRIEF DESCRIPTION OF THE DRAWINGS

Implementations of the present disclosure are illustrated by way of example, and not by way of limitation, in the Figures of the accompanying drawings. It should be noted that different references to “an” or “one” implementation in this disclosure are not necessarily to the same implementation, and such references may mean at least one. Further, when a particular feature, structure, or characteristic is described in connection with an implementation, it is submitted that it is within the knowledge of one skilled in the art to effect such feature, structure, or characteristic in connection with other implementations whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1 depicts a representative Group III-V semiconductor device including an in-situ surface passivation layer according to some examples of the present disclosure;

FIG. 2 depicts a block diagram of a semiconductor processing tool for fabricating a representative Group III-V semiconductor device having an in-situ surface passivation layer according to some examples of the present disclosure;

FIGS. 3-5 are flowcharts relating to semiconductor device fabrication methods according to some examples of the present disclosure; and

FIG. 6 depicts an illustrative Group III-V stack having a composite passivation layer according to an example of the present disclosure.

### DETAILED DESCRIPTION

Examples of the disclosure are described with reference to the attached Figures wherein like reference numerals are generally utilized to refer to like elements. The Figures are not drawn to scale and they are provided merely to illustrate examples. Numerous specific details, relationships, and/or methods are set forth below to provide an understanding of one or more examples. However, it should be understood that some examples may be practiced without such specific details. In other instances, well-known subsystems, circuits, components, structures and techniques have not been shown in detail in order not to obscure the understanding of the examples. Accordingly, it will be appreciated by one skilled in the art that the examples of the present disclosure may be practiced without such specific components, structures or subsystems, etc.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. “Directly connected” may be used to convey that two or more physical features touch, or share an interface between each other. Further, in one or more examples set forth herein, generally speaking, an element, component or module may be configured to perform a function if the element may be programmed for performing or otherwise structurally arranged to perform that function.

Without limitation, examples of the present disclosure are set forth below in the context of fabricating Group III nitride devices (e.g., gallium nitride or GaN devices) as a representative class of semiconductor devices known as high-electron-mobility transistor (HEMT) devices based on compound semiconductors such as Group III-V materials.

GaN devices have attracted great attention due to their ability to operate at higher frequencies and voltages better than silicon devices. It is known, however, that GaN transistors experience increased effective on-state resistance when switched at high voltage and frequency due to charge trapping in the device. This increased resistance (often more than twice with respect to DC) is variously known as current collapse, dynamic on-state resistance, or dynamic R_{Dson}.

Another type of GaN device failure is Time-Dependent Dielectric Breakdown (TDDB), which occurs when a high electric field exists across the gate dielectric causing defects to be generated. These defects eventually form a conduction path through the dielectric, rendering the device unusable. This is a major concern in GaN HEMTs because they are typically used as switches in high voltage circuits and spend a significant amount of time in the off-state, thereby having to block the high voltage being applied to the drain over extended periods of time. The high voltage difference between the drain and the gate forms a strong electric field across the gate dielectric, which can cause defect formation and subsequent dielectric failure.

To address the foregoing concerns, in-situ surface passivation may be provided in the fabrication of GaN devices according to some examples. In such arrangements, the same equipment used for growing the epitaxial layers of appropriate compound semiconductor materials over suitable substrates (e.g., in a metal organic chemical vapor-phase deposition or MOCVD reactor) is also used for depositing a silicon nitride (SiN) dielectric layer as a passivation layer on a top epitaxial layer. The in-situ formed SiN layer helps preserve the integrity of the surface condition of the top epitaxial layer, thereby resulting in a low density of interface defectivity (e.g., such as dislocations, stacking faults, etc.), which in turn facilitates low dynamic RDs on as well as improved TDDB performance. However, using precursors such as ammonia (NH₃) for growing Group III nitride epitaxial layers over silicon-based substrates and/or forming in-situ SiN passivation layers can give rise to various Si_{X}N_{Y} species as byproducts that can be accumulated as residual material in the interior space of an MOCVD reactor chamber and on the surfaces of the components disposed therein. Over time, without proper cleaning, the Si_{X}N_{Y} residual material can flake off or otherwise become disassociated from the surfaces inside the reactor chamber and adversely impact subsequent processing operations in the chamber. As such, chemistries used for removing GaN residual deposits from the reactor chamber are not effective for cleaning Si_{X}N_{Y} byproducts accumulated in the reactor chamber. Further, if the Si_{X}N_{Y} residual material is not cleaned properly, the chemistry used to remove Group III nitride deposits may not be applied effectively because of the buildup of the Si_{X}N_{Y} residual material over the Group III nitride deposits, especially where in-situ SiN passivation is the last step of the processing of a semiconductor wafer in the reactor chamber. Accumulation of Si_{X}N_{Y} residual material and/or Group III nitride residual material inside the reactor chamber can therefore have deleterious effects on the processing of semiconductor wafers in a Group III-V fabrication flow.

Examples described herein recognize the foregoing challenges and accordingly provide a multistage chamber cleaning process wherein a plasma-based cleaning stage may be augmented as part of a fabrication flow. In some examples, the plasma-based cleaning stage may be performed periodically to clean the accumulated Si_{X}N_{Y} residual material in an MOCVD reactor chamber. Further, the removal of Si_{X}N_{Y} residual material in turn facilitates the cleaning of Group III nitride (e.g., GaN) deposits from the reactor chamber using a baseline cleaning process according to some implementations. While such example arrangements may be expected to provide various tangible improvements over baseline processes, no particular result is a requirement unless explicitly recited in a particular claim.

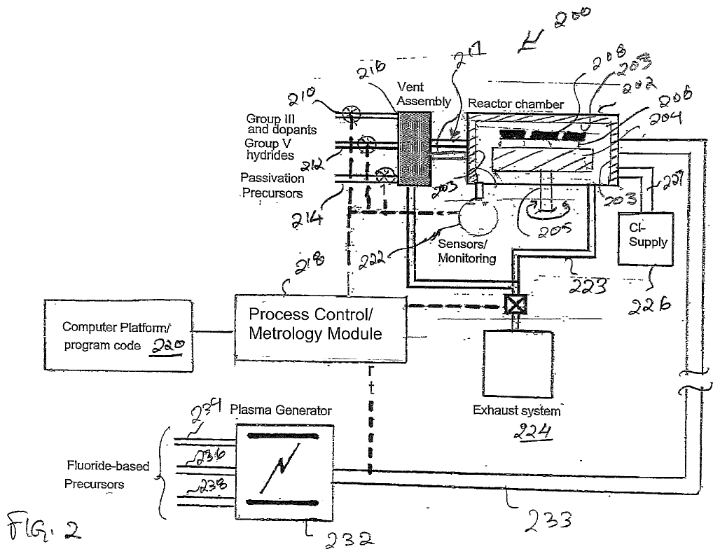

Referring to the drawings, in particular FIG. 2, depicted therein is a block diagram of a semiconductor processing tool 200 for fabricating a representative Group III-V semiconductor device having an in-situ surface passivation layer according to some examples of the present disclosure. As illustrated, the semiconductor processing tool 200 comprises an MOCVD reactor chamber 202 configured to grow Group III-V semiconductor layers as well as deposit in-situ surface passivation layers over one or more process wafers 208 using appropriate chemical species and processing recipes depending on the fabrication flow. With respect to the formation Group III-V layers, various Group III materials and dopants as well as Group V hydrides may be provided as precursors via vapor transport facilitated by respective delivery systems 210, 212 to the reactor chamber. In one arrangement, alkylated compounds having an organic group, e.g., trimethyl gallium (TMG), trimethyl aluminum (TMA) or trimethyl indium (TMI), etc., as well as suitable dopant species (optional in some examples), may be supplied or directed to the reactor chamber 202 as precursor materials for growing an alloy of a Group III compound. Depending on implementation, passivation precursors such as, e.g., mixtures of silane (SiH₄) and ammonia (NH₃) or trimethyl amine (TMAm), a metalorganic source of silicon, and NH₃, may be supplied or directed via a delivery system 214 at a passivation stage of the flow for forming a nitride layer after the formation of one or more epitaxial layers. Although not specifically shown in this figure, there may be an extensive arrangement of bubbler systems associated with delivery systems 210, 212, 214 that receive carrier gasses at controlled flow rates, temperatures and pressures, which may be mixed with appropriate compounds disposed in the bubblers for supplying respective chemical species to the reactor chamber 202 in a controlled manner depending on the process flow recipes. For the sake of simplicity, a generalized vent assembly or manifold system 216 representing one or more bubbler systems is illustrated herein, which may be coupled to an overall exhaust system 224 associated with the reactor chamber 202 in an example arrangement. In some arrangements, however, each bubbler system may have its own separate exhaust facility. A plurality of ingress pipes 217 may be disposed for transporting the carrier materials to the reactor chamber 202, wherein a suitable dispersal system may be provided (not specifically shown) for introducing the materials into the reactor chamber 202.

In an example arrangement, the reactor chamber 202 may comprise a planetary disc type reactor chamber, a shower head type reactor chamber, etc., which may be coupled to the exhaust system 224 via one or more egress pipes 223. Depending on implementation and processing conditions, the reactor chamber 202 may be configured to operate at a range of temperatures and pressures, including particular temperatures and pressures for facilitating multi-stage cleaning processes according to some examples herein, as will be set forth further below. Regardless of the type of reactor chamber 202, a susceptor 206 may be disposed therein for holding one or more semiconductor process wafers 208 for the epitaxial growth phase and subsequent in-situ nitride passivation stages during a process run. In some arrangements, the susceptor 206 may be disposed on or otherwise coupled to a platform 204 having a shaft 205 that may rotate or spin around a vertical axis at speeds in a range from zero to several hundreds or thousands of rpm. The susceptor 206 and/or the platform 204 may be heated using a variety of heating subsystems such as, e.g., radio frequency (RF) coils, resistance-heated coils, radiantly heated strip lamps, etc., in order to bring the temperatures of the semiconductor process wafers 208 to a suitable range during the fabrication of one or more epitaxial layers.

In an example planetary disc type reactor chamber arrangement, carrier gases may be introduced into the chamber 202 through a gas inlet or nozzle located in the center of the chamber ceiling (not shown in this figure). A pump system may be provided for extracting the gases and dispersing them radially from the center for uniformly dispersing over the process wafers 208. In an example shower head type reactor chamber, the carrier gases may enter through a large number of gas channels in the reactor ceiling (not shown in this FIG.), which may be vertically distributed evenly over the process wafers 208. When the carrier gases for epitaxial growth are introduced in the reactor chamber 202 having suitable ambient processing conditions, the chemical species are decomposed, with constituent atoms interacting with the surface of the heated process wafers or of the previously formed layer thereon for growing an overlying layer essentially at an atomic scale. Gaseous byproducts and/or unused gases may be purged by the exhaust system 224 via the egress pipes 223. In some arrangements, various sensors (e.g., temperature sensors, pressure sensors, etc.) may be deployed at different locations of the tool system 200, including, e.g., source gas systems (not specifically shown), delivery systems 210, 213, 214, vent assembly system(s) 216, exhaust system(s) 224, as well as in-situ sensors for monitoring ambient conditions of the reactor chamber 202 and any interior components therein, which may be collectively shown as sensors and monitoring systems 222 by way of illustration. In some examples, a process control and metrology module 218 associated with a computer platform 220 may be operable under suitable program control, e.g., in response to the sensor output, for effectuating various fabrication processes set forth herein. In some examples, the computer platform 220 may also be configured to effectuate a two-stage cleaning methodology using respective processing conditions and chemistries for removing residual SiN and GaN deposits from interior wall surfaces 203 of the reactor chamber 202 and from any interior components disposed therein as will be set forth in detail further below.

Whereas NH₃ may be provided as a Group V hydride in some arrangements, other Group V hydrides such as phosphides, antimonides or arsenides may also be supplied in additional and/or alternative implementations of a Group III-V fabrication flow. Although the formation of epitaxial layers involving non-nitrogen hydrides may not cause an intrinsic silicon nitride (Si_{X}N_{Y}) buildup (because there is no nitrogen), if a nitride-based in-situ passivation process is implemented in the reactor chamber 202 as part of an example flow, such a process may engender Si_{X}N_{Y} buildup due to the reactive species (e.g., NH₃) used in some passivation recipes. On the other hand, where NH₃ is supplied as a Group V hydride for the growth of epitaxial layers, there can be an intrinsic SiN buildup even if the passivation chemistry does not involve nitrogen. Accordingly, where there is a nitride-based in-situ passivation process implemented in addition to the formation of Group III-N epitaxial layers, SiN residual material may be generated in the reactor chamber 202 because of two distinct processes: (i) due to the interaction of the reactive precursor species intentionally introduced in the surface passivation chemistry; and (ii) as an intrinsic byproduct of the epitaxial growth process.

Further, components enclosed in the reactor chamber 202 such as, e.g., susceptor 206, platform 204, etc. (referred to as interior components for purposes herein) may comprise parts or segments made of silicon carbide (SiC), and/or carbide-coated structures in some arrangements. Because such components contain silicon that can also interact with reactive NH₃ species in the reactor chamber 202 (either during Group III-N growth and/or in nitride passivation process), additional Si_{X}N_{Y} residual material may be accumulated on the surfaces of the components, thereby giving rise to further contamination.

Regardless of how Si_{X}N_{Y} residual material is generated in the reactor chamber 202, the tool system 200 may include or otherwise be associated with a plasma generator 232 for generating fluorine-based reactive species from suitable precursors, e.g., selected from one or more of SF₆, F₂, NF₃, and the like, that may be directed to the reactor chamber 202 for removing the accumulated layers of Si_{X}N_{Y} residual material from interior wall and ceiling surface(s) 203 and/or from one or more interior components. By way of illustration, various precursor gases may be supplied to the plasma generator 232 using one or more intake delivery systems 234, 236, 238, wherein an ionized gas (i.e., plasma) containing the reactive species may be generated, which may be transported in an egress delivery system 233 for delivery. Depending on implementation, various types of plasma generators or reactors may be configured for purposes of the removal of Si_{X}N_{Y} residual material according to some examples of the present disclosure. By way of illustration, barrel reactors, parallel plate reactors, etc., may be deployed, which may vary in terms of excitation frequencies (e.g., 5 kHz to 5 GHz), operating pressures (e.g., 1 millibar to 1 atm, or 100 Pa to 1E5 Pa), electrode arrangement, etc. Also, an example plasma generator 232 of the tool system 200 may be based on inductively coupled RF plasmas, capacitively coupled RF plasmas, electron cyclotron resonance plasmas, etc., wherein appropriate source gas chemistries may be deployed.

In one arrangement, the process of plasma generation and delivery may be programmatically controlled under the execution of a process control module effectuated by the computer platform 220 associated with the tool system 200. In another arrangement, a separate process control platform may be provided with respect to the plasma generator 232 and associated subsystems. Regardless of how the process control for plasma generation is implemented, reactive species may be generated at one place and carried downstream to a place or chamber or enclosure, e.g., reactor chamber 202, that carries out the epitaxial growth and surface passivation processes, for cleaning Si_{X}N_{Y} residual material in a first cleaning process of a two-stage cleaning process designed to clean the chamber before or after wafer processing. In one arrangement, the tool system 200 may include an in-situ chlorine supply 226 for providing chlorine-containing species in a heated gas via a suitable distribution/dispersal system 227 for removing Group III nitride residual material in a second cleaning process following the first cleaning process. Whereas the fluorine-based reactive species may be provided in a remote plasma generation process as shown in the example of FIG. 2, some arrangements having an MOCVD reactor built to withstand the conditions of in-situ plasma generation may be configured to have suitable fluorine-based reactive species locally supplied similar to the chlorine supply 226.

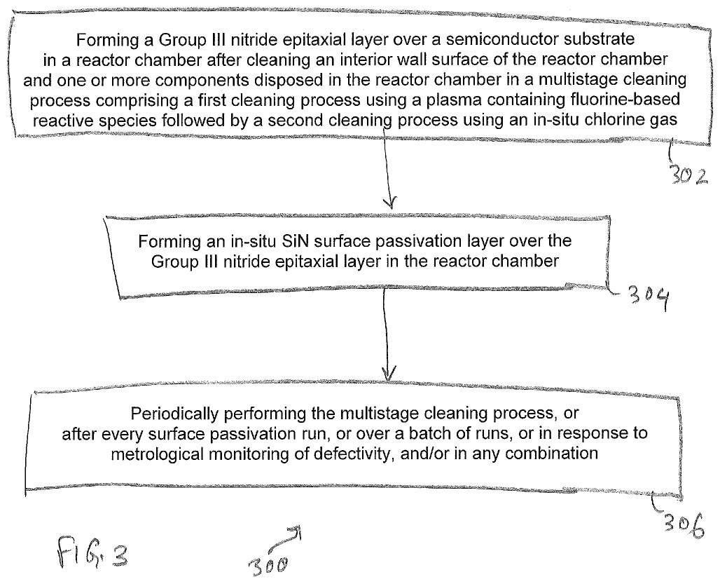

FIGS. 3-5 are flowcharts relating to semiconductor fabrication methods and associated cleaning processes according to some examples of the present disclosure, wherein the blocks, steps, acts and/or functions of one flowchart may be intermixed with the blocks, steps, acts and/or functions of other flowcharts in one or more permutations and/or combinations depending on implementation. Process 300 of FIG. 3 is illustrative of an example IC device fabrication method. At block 302, a Group III nitride epitaxial layer may be formed over a semiconductor substrate in a reactor chamber after cleaning an interior wall surface of the reactor chamber and/or one or more components disposed in the reactor chamber in a multistage cleaning process. In one arrangement, the multistage cleaning process may comprise a first cleaning process using a plasma containing fluorine-based reactive species followed by a second cleaning process using a heated chlorine gas supplied in-situ. In some arrangements, the cleaning sequences of the plasma containing fluorine-based reactive species and the chlorine-based chemistry may be applied in a reverse order. At block 304, an in-situ SiN surface passivation layer may be formed over the Group III nitride epitaxial layer in the reactor chamber. In some arrangements, the reactor chamber may be periodically cleaned using a scheduled multistage cleaning process, e.g., once or twice every day, every week, etc. In some arrangements, an example multistage cleaning process may be performed after every batch of semiconductors wafers are processed in the reactor chamber, e.g., after every SiN surface passivation run where the formation of a SiN surface passivation layer is the final step in the processing of a batch of semiconductor wafers after the epitaxial layer formation in the reactor chamber. In some arrangements, the multistage cleaning process may be performed on-demand, e.g., in response to metrological notifications relating to the level of Si_{X}N_{Y} residual material and/or Group III nitride residual material accumulated in the reactor chamber, downstream defectivity assignable to MOCVD contaminants, etc. In some arrangements, an example multistage cleaning process may be performed as a combination of the foregoing processes under programmatic control executed by a computer platform associated with the reactor chamber as set forth hereinabove (block 306).

Example SiN surface passivation processes may be based on compositions comprising SiH₄ and NH₃ or TMAm and NH₃ as previously noted, although other chemistries may also be used in some fabrication flows. Whereas SiN surface passivation is performed in an MOCVD reactor, the composition of a SiN surface passivation layer is in general amorphous (e.g., non-epitaxy), and may comprise a thin layer of dielectric nitride material of about 1 nm to 200 nm in some examples.

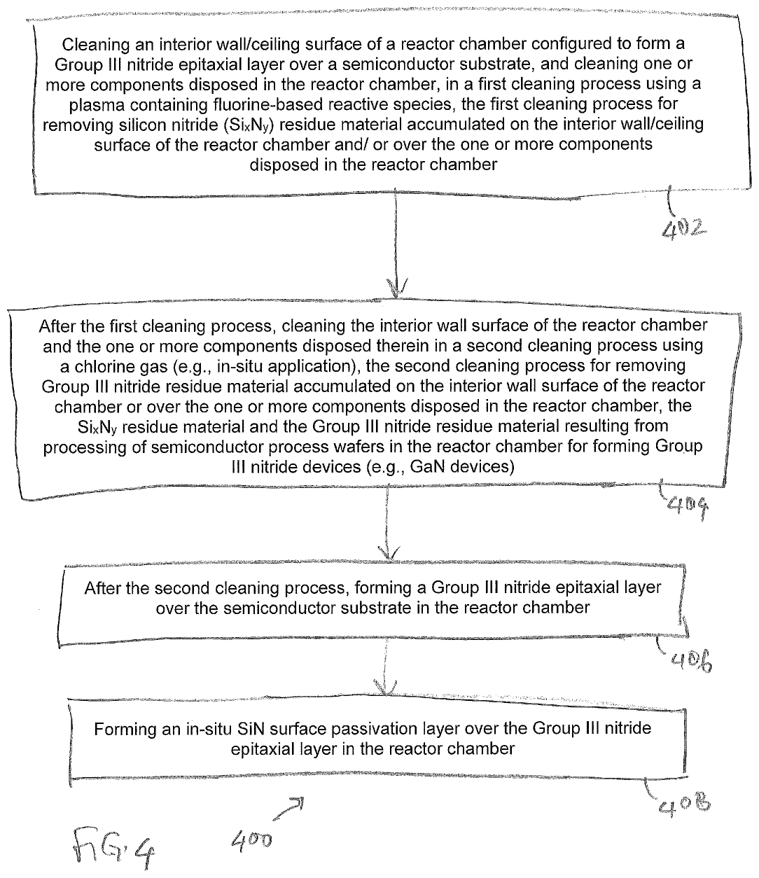

Example process 400 shown in FIG. 4 is illustrative of a method including a multistage cleaning process, which may commence with cleaning an interior wall surface of a reactor chamber configured to form a Group III nitride epitaxial layer over a semiconductor substrate, and cleaning one or more components disposed in the reactor chamber, in a first cleaning process using a plasma containing fluorine-based reactive species (block 402). In one arrangement, the first cleaning process may be configured for removing SiₓN_{y} residue material accumulated on the interior wall surface of the reactor chamber and/or over the one or more components disposed in the reactor chamber. After the first cleaning process, example process 400 may involve cleaning the interior wall surface of the reactor chamber and the one or more components disposed therein in a second cleaning process using a chlorine gas (e.g., in-situ application), as set forth at block 404. In one arrangement, the second cleaning process may be configured for removing Group III nitride residue material accumulated on the interior wall surface of the reactor chamber or over the one or more components disposed in the reactor chamber. In one arrangement, the accumulated SiₓN_{y} residue material and the Group III nitride residue material may comprise byproducts resulting from processing of semiconductor process wafers in the reactor chamber for forming Group III nitride devices (e.g., GaN devices). As part of an IC fabrication method, process 400 may include a step, after the second cleaning process, wherein a Group III nitride epitaxial layer may be formed over the semiconductor substrate in the reactor chamber, as set forth at block 406. Subsequently, a surface passivation layer may be formed over the Group III nitride epitaxial layer in the reactor chamber (e.g., in-situ SiN deposition), as set forth at block 408.

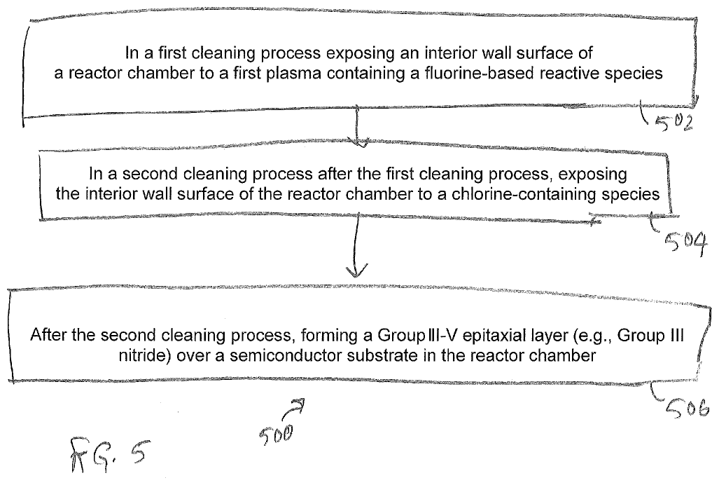

Example process 500 shown in FIG. 5 is illustrative of a method of forming a Group III nitride layer in a fabrication flow. As exemplified, a first cleaning process is operative for exposing an interior wall surface of a reactor chamber to a first plasma containing a fluorine-containing reactive species (block 502). In a second cleaning process after the first cleaning process, the interior wall surface of the reactor chamber may be exposed to a chlorine-containing species. Because the respective cleaning processes may be configured to remove residual SiN and Group III nitride accumulations in the reactor chamber (which may be deemed as contaminant layers in the reactor chamber) in a sequential manner, the removal of respective residue materials may be deemed de-layering processes in some examples. After the second cleaning process, a Group III-V epitaxial layer (e.g., Group III nitride) may be formed over a semiconductor substrate in the reactor chamber. In some arrangements, therefore, a method of semiconductor fabrication may involve a de-layering process of a reactor chamber followed by loading of process wafers in the reactor chamber, and a subsequent layering process of Group III-V epitaxial growth and in-situ surface passivation. In another variation, a method of semiconductor fabrication may involve introduction of process wafers in a reactor chamber followed by a layering process of Group III-V epitaxial growth and in-situ surface passivation in the reactor chamber, and a subsequent de-layering process of the reactor chamber involving a two-stage cleaning process.

Because example cleaning processes may involve fluorine-based reactive species in a first cleaning process, there may be an undesirable side effect of etching of quartz windows or ports (as well as quartz-containing components) implemented in some reactor chambers, which may affect the integrity of such components. Some examples of the present disclosure may therefore include purging of the quartz components with an inert gas, e.g., nitrogen, during the first cleaning process.

In some examples involving a multistage cleaning process, the reactor chamber may be maintained at a temperature of about 350° C. during the first and second cleaning processes. A chamber pressure of about 2 torr (266 Pa) and a flow rate of NF₃ (ionized remotely) at about 1500 standard cubic centimeters per minute (sccm) may be maintained in the first cleaning process, with an example exposure time of about 25-40 minutes. Skilled artisans will recognize upon reference hereto that various combinations of cleaning process conditions may be applied depending on a fabrication flow. By way of illustration, examples of a first cleaning process may involve process conditions comprising temperatures ranging from 25° C. to 1200° C., ionizable fluorine-containing gas with a flow rate ranging from 100 sccm to 5000 sccm, and having a pressure in the range of 0.5 torr (67 Pa) to 100 torr (13.3 kPa).

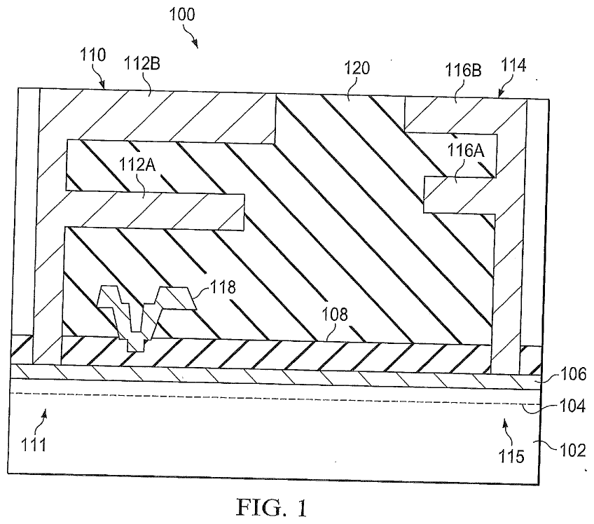

Turning to FIG. 1, depicted therein is a cross-sectional view of a representative Group III-V semiconductor device, e.g., GaN device 100, including an in-situ surface passivation layer according to some examples of the present disclosure. In one arrangement, a passivation process involving a process recipe for optimizing a combination of device performance characteristics, e.g., TDDB, R_{Dson}, etc., may be used for depositing a single SiN layer in an MOCVD reactor chamber. In another arrangement, the process recipe may involve depositing multiple SiN layers or sub-layers, each operative for optimizing a particular performance parameter, as a composite passivation layer. In an example implementation, the GaN device 100 may include a layer 106 of aluminum gallium nitride (AlGaN) epitaxially grown over a GaN layer 102, which in turn may be formed over a substrate material (not specifically shown in this FIG.). Because the AlGaN layer 106 and the GaN layer 102 exhibit different bandgaps, they are said to meet at a heterojunction. Under suitable conditions, a 2-dimensional electron gas (2DEG) channel 104 may be formed at the heterojunction interface of the GaN and AlGaN layers 102, 106. In the 2DEG channel 104, some electrons are unbound to atoms and free to move, providing higher mobility as compared with other types of transistors. Accordingly, little or no doping of the substrate may be required for operation of the GaN device 100. A source contact or terminal 110, a drain contact or terminal 114 and a gate contact or terminal 118 may be formed with respect to an active area of the device 100. An optional substrate terminal may be provided at a lower portion of the device but this is not a requirement. Whereas in a normally ON mode device (i.e., a depletion mode device), the 2DEG channel extends from source region 111 to drain region 115 of the device without any discontinuity, as illustrated in FIG. 1, in an enhancement mode device (i.e., a normally OFF mode device), the channel is absent in a gate region associated with gate terminal 118 until the device is turned on.

In some arrangements, one or more field plates may be optionally provided in association with one or more of the device terminals, e.g., source 110, drain 114 and/or gate 118, to mitigate the effects of peak electric fields on the channel caused by the high voltage operation of the device 100. By way of illustration, source field plates 112A, 112B and drain field plates 116A, 116B are exemplified in FIG. 1, which may extend laterally into an inter-level dielectric (ILD) insulator layer 120 and may be covered by a protective overcoat (PO) (not shown in this figure) of the device 100.

Surface passivation layer 108 of the GaN device 100 may be deposited over the entire AlGaN layer 106 using suitable dielectric materials (e.g., silicon nitride (SiN)) in an in-situ deposition process prior to patterning a gate region opening therein for facilitating the deposition of gate dielectric material (not specifically shown in this figure) and subsequent formation of gate terminal 118. In one example implementation, prior to growing any epitaxial layers, e.g., the GaN layer 102, over a substrate, the reactor chamber may be exposed to a two-stage cleaning process according to some examples herein. Thereafter, a first epitaxial layer comprising GaN layer 102 and a second epitaxial layer comprising AlGaN layer 106 may be formed. For purposes for growing the AlGaN layer 106 as a second epitaxial layer, the underlying structure of GaN layer 102 over the substrate material may be operative as a composite semiconductor substrate. In some examples, AlGaN layer 106 may have a thickness of about 20 nm to 30 nm and GaN layer 102 may have a thickness ranging from tens of nanometers to one or more microns (μm), although other variations are possible depending on breakdown voltage requirements and other considerations. After the formation of the AlGaN layer 106, SiN surface passivation layer 108 may be formed in-situ using a suitable chemistry as previously noted. In some examples, nitride deposition processes in an oxygen environment may also be used for surface passivation, some of which may be in-situ and some of which may be in a different chamber. By way of illustration, a surface passivation layer may comprise an SiN layer of about 65 nm, e.g., with a range of about ±5%, formed by a CVD process using an oxygen (O₂)-rich environment (e.g., O₂ levels of approximately 600 parts per million (ppm) to 1000 ppm). In another example, a surface passivation layer may comprise an SiN layer of about 35 nm, e.g., with a range of about ±5%, formed by a CVD process using an O₂ level less than approximately 30 ppm. As skilled artisans will recognize upon reference hereto, example surface passivation processes disclosed herein may have various temperature and pressure conditions associated therewith as well.

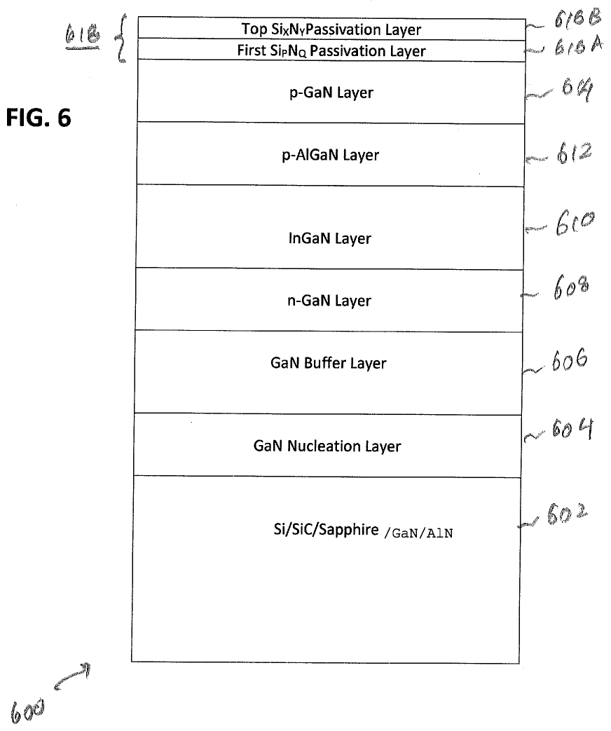

FIG. 6 depicts an illustrative Group III-V stack having a composite passivation layer according to an example of the present disclosure. By way of illustration, a substrate 602 may comprise silicon, silicon carbide or sapphire, AlN, GaN, Al_{X}Ga_{Y}N_{z}, etc., over which a plurality of epitaxial layers may be grown in an MOCVD reactor chamber. As noted previously, prior to growing any Group III epitaxial layer over the substrate 602, a two-stage cleaning process may be applied to the reactor chamber for cleaning residual Si_{X}N_{Y} material and Group III nitride material from the reactor chamber and any interior components therein. A GaN nucleation layer 604 may be grown initially, over which a GaN buffer layer 606 may be formed. Thereafter, an n-doped GaN layer 608 may be formed over the GaN buffer layer. An InGaN layer 610 may be formed over the n-doped GaN layer 608. A p-doped AlGaN layer 612 may be formed over InGaN layer 610. A p-doped GaN layer 614 may be formed as a top Group III epitaxial layer over p-doped AlGaN layer 612. A first surface passivation layer 616A and a second, or top, surface passivation layer 616B may be formed in-situ, which may comprise different ratios of Si to N, respectively, and form a composite passivation layer 618 for purposes of an example arrangement.

Although some examples set forth above are primarily directed to GaN-based devices, it will be understood that the disclosed devices, methods and fabrication tools are not so limited. For example, the active layers of a device may comprise a composition having multiple Group III elements, e.g., AlₓIn_{Y}Ga_{(1-X-Y)}N, where X, Y and (1-X-Y) refer to relative portions of aluminum, indium and gallium, respectively. In some additional and/or alternative arrangements, the active layers may comprise B_{w}AlₓIn_{y}Ga_{z}N materials, in which w, x, y and z each has a suitable fractional value between zero and one (inclusive). The reference herein to B_{w}AlₓIn_{y}Ga_{z}N or a B_{w}AlₓIn_{y}Ga_{z}N material may refer to a semiconductor material having nitride and one or more of boron, aluminum, indium and gallium or a sub-combination thereof. Examples of B_{w}AlₓIn_{y}Ga_{z}N materials include GaN, AlN, AlGaN, AlInGaN, InGaN, and BAlInGaN, by way of illustration. A B_{w}AlₓIn_{y}Ga_{z}N material may include other materials besides nitride, boron, aluminum, indium and/or gallium. For example, a B_{w}AlₓIn_{y}Ga_{z}N material may be doped with a suitable dopant such as silicon, germanium, and the like

At least some examples are described herein with reference to one or more tool schematics, block diagrams and/or flowchart illustrations. It is understood that such diagrams and/or flowchart illustrations, and combinations of blocks in the block diagrams and/or flowchart illustrations, can be implemented in numerous ways to achieve the desired functionalities. Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

It should therefore be clearly understood that the order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure.

At least some portions of the foregoing description may include certain directional terminology, which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged mutatis mutandis, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” All structural and functional equivalents to the elements of the above-described implementations that are known to those of ordinary skill in the art are expressly incorporated herein by reference and are intended to be encompassed by the claims appended below.

What is claimed is:

1. A method of fabricating an integrated circuit, the method comprising:
cleaning an interior wall surface of a reactor chamber configured to form a Group III nitride epitaxial layer over a semiconductor substrate, and cleaning one or more components disposed in the reactor chamber, in a first cleaning process using a plasma containing fluorine-based reactive species;
after the first cleaning process, cleaning the interior wall surface of the reactor chamber and the one or more components disposed therein in a second cleaning process using chlorine gas; and
after the second cleaning process, forming the Group III nitride epitaxial layer over the semiconductor substrate in the reactor chamber.

2. The method as recited in claim 1, wherein the first cleaning process removes silicon nitride (SiₓN_{y}) residue material and the second cleaning process removes Group III nitride residue material.

3. The method as recited in claim 2, wherein the SiₓN_{y} residue material and the Group III nitride residue material comprise byproducts resulting from processing of semiconductor process wafers in the reactor chamber for forming Group III-V devices.

4. The method as recited in claim 1, wherein the plasma containing fluorine-based reactive species is formed from one or more of SF₆, F₂ and NF₃, the plasma supplied from a remote plasma generator.

5. The method as recited in claim 1, wherein the first cleaning process is performed periodically for cleaning the SiₓN_{y} residue material at regular intervals.

6. The method as recited in claim 1, wherein further comprising forming an in-situ SiN surface passivation layer over the Group III nitride epitaxial layer in the reactor chamber.

7. The method as recited in claim 6, wherein the first cleaning process is performed after every in-situ SiN surface passivation layer run in the reactor chamber.

8. The method as recited in claim 18, wherein the Group III nitride epitaxial layer is formed as a top layer of a Group III-V stack of epitaxial layers.

9. A method of forming a Group III nitride layer, comprising:
in a first cleaning process exposing an interior wall surface of a reactor chamber to a first plasma containing a fluorine-containing reactive species;
in a second cleaning process after the first cleaning process, exposing the interior wall surface of the reactor chamber to a chlorine-containing species;
after the second cleaning process, forming the Group III nitride epitaxial layer over a semiconductor substrate in the reactor chamber.

10. The method as recited in claim 9, wherein an in-situ chlorine gas supply provides the chlorine-containing species.

11. The method as recited in claim 9, wherein the chlorine-containing species is provided as a second plasma.

12. The method as recited in claim 9, wherein the fluorine-containing reactive species is provided by one or more of SF₆, F₂ and NF₃.

12. The method as recited in claim 9, wherein the first plasma is a remotely generated plasma.

13. The method as recited in claim 9, wherein the chamber is at a temperature of about 350° C. during the first and second cleaning processes.

14. The method as recited in claim 13, wherein during the first cleaning process a chamber pressure is about 2 torr (266 Pa) and a flow rate of NF₃ is about 1500 standard cubic centimeters per minute (sccm).

15. The method as recited in claim 9, wherein the first cleaning process removes Si_{w}Nₓ from one or more silicon carbide (SiC) segments of components disposed in the reactor chamber and the second cleaning process removes Ga_{y}N_{z} from the one or more SiC segments of the components disposed in the reactor chamber.

16. The method as recited in claim 9, wherein the first cleaning process removes Si_{w}Nₓ from the interior wall surface and the second cleaning process removes Ga_{y}N_{z} from the interior wall.

17. A semiconductor processing tool, comprising:
a reactor chamber configured to form one or more Group III-V epitaxial layers over a semiconductor substrate, the reactor chamber further configured to deposit one or more surface passivation layers over a top Group III-V epitaxial layer;
a delivery system for directing one or more Group III precursors and one or more Group V precursors to the reactor chamber;
a delivery system for directing chemical species to the reactor chamber for forming the one or more surface passivation layers comprising silicon nitride (SiN);
a plasma generator for generating a plasma containing fluorine-based reactive species;
a delivery system for directing the fluorine-based reactive species to the reaction chamber; and
an in-situ cleaning system configured to provide chlorine-based species to the reactor chamber.

18. The semiconductor processing tool as recited in claim 17, wherein the plasma containing the fluorine-based reactive species is operable for cleaning silicon nitride (SiₓN_{y}) residue material accumulated on an interior wall surface of the reactor chamber or over one or more components disposed in the reactor chamber.

19. The semiconductor processing tool as recited in claim 17, wherein the chlorine-based species is operable for removing Group III nitride residue material accumulated on the interior wall surface of the reactor chamber or over the one or more components disposed in the reactor.

20. The semiconductor processing tool as recited in claim 17, wherein the plasma generator is configured to generate the fluorine-based reactive species comprising species formed from at least one of SF₆, F₂ and NF₃.

21. The semiconductor processing tool as recited in claim 17, wherein the plasma generator is configured to be activated periodically to generate the fluorine-based reactive species for cleaning SiₓN_{y} residue material at regular intervals from an interior wall surface of the reactor chamber or over one or more components disposed in the reactor chamber.

22. The semiconductor processing tool as recited in claim 17, wherein the plasma generator is configured to be activated after a top surface passivation layer run comprising deposition of SiN over a batch of semiconductor process wafers in the reactor chamber.

23. The semiconductor processing tool as recited in claim 17, wherein the plasma generator is a remote plasma generator configured to form the fluorine-based reactive species in a chamber separate from the reactor chamber.
